(19) United States
(12) Patent Application Publication
(10) Pub. No.: US 2017/0047238 A1
(43) Pub. Date: Feb. 16, 2017

(54) ANNULAR EDGE SEAL WITH CONVEX INNER SURFACE FOR ELECTROSTATIC CHUCK

(71) Applicant: Lam Research Corporation, Fremont, CA (US)

(72) Inventor: Matthew Michael Lee, Los Altos, CA (US)

(21) Appl. No.: 14/836,202

(22) Filed: Aug. 26, 2015

Related U.S. Application Data
(60) Provisional application No. 62/203,118, filed on Aug. 10, 2015.

(51) Int. Cl. H01L 21/683; F16J 15/02; H01J 37/32

(52) U.S. Cl. CPC H01L 21/6833; H01J 37/32715; F16J 15/02

(57) ABSTRACT

An edge seal is arranged in an annular slot formed in an electrostatic chuck of a substrate processing system. The edge seal includes an annular body, a radially inner surface, a radially outer surface, a top surface, and a bottom surface. The radially inner surface is convex. The radially outer surface, the top surface and the bottom surface are generally planar.

### CROSS-REFERENCE TO RELATED APPLICATIONS

This application claims the benefit of U.S. Provisional Application No. 62/203,118, filed on Aug. 10, 2015. The entire disclosure of the application referenced above is incorporated herein by reference.

### FIELD

The present disclosure relates to substrate processing systems, and more particularly to edge seals used in substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems include a processing chamber with a substrate support. A substrate such as a semiconductor wafer is arranged on the substrate support during processing. In some systems, the substrate support includes an electrostatic chuck (ESC). During substrate treatment such as etching, chemical vapor deposition (CVD), atomic layer deposition (ALD) or atomic layer etching (ALE), gas mixtures may be introduced into the processing chamber. Radio frequency (RF) plasma may be used during processing to activate chemical reactions. Components located within the substrate processing system need to be able to withstand the plasma and/or gas chemistry that is used during processing.

The ESC may include an edge seal that protects adhesive bonding layers that are used to bond a heater plate to a ceramic top plate of the ESC. When left unprotected, the adhesive bonding layers are damaged and particle contamination occurs. If the adhesive bonding layers are heavily eroded, the ESC may be permanently damaged.

### SUMMARY

An edge seal for an electrostatic chuck of a substrate processing system includes an annular body, a radially inner surface, a radially outer surface, a top surface, and a bottom surface. The radially inner surface is convex.

In other features, corners between the radially inner surface, the radially outer surface, the top surface and the bottom surface are radiused. The radially outer surface of the body is generally planar between a first corner between the top surface and the radially outer surface and a second corner between the bottom surface and the radially outer surface.

In other features, the top surface of the body is generally planar between a third corner between the top surface and the radially inner surface and a fourth corner between the top surface and the radially outer surface. The bottom surface of the body is generally planar between the fourth corner between the bottom surface and the radially inner surface and the second corner between the bottom surface and the radially outer surface. The radially inner surface of the body is convex between the third corner between the top surface and the radially inner surface and the first corner between the bottom surface and the radially inner surface.

In other features, a radial thickness of the body at a center of the body is 10% to 30% greater than a radial thickness of the body adjacent to the top surface and the bottom surface. A radial thickness of the body at a center of the body is 15% to 25% greater than a radial thickness of the body adjacent to the top surface and the bottom surface. A radial thickness of the body at a center of the body is 20% to 24% greater than a radial thickness of the body adjacent to the top surface and the bottom surface.

An electrostatic chuck includes an upper layer, an intermediate layer, a lower layer, a first adhesive bonding layer arranged between the upper layer and the intermediate layer, and a second adhesive bonding layer arranged between the intermediate layer and the lower layer. Radially outer edges of the intermediate layer and the first and second adhesive bonding layers form an annular slot relative to the upper layer and the lower layer. The edge seal is arranged in the annular slot.

In other features, the upper layer includes a ceramic layer, the intermediate layer includes a heater plate and the lower layer includes a lower electrode. The first and second adhesive bonding layers include elastomeric silicone. The first and second adhesive bonding layers include silicone rubber.

A substrate processing system includes a processing chamber, a gas delivery system to deliver process gas to the processing chamber, a plasma generator to generate plasma in the processing chamber, and the electrostatic chuck.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a substrate processing system including an electrostatic chuck (ESC) according to the present disclosure;

FIG. 2 is a surface cross-sectional view of a lower electrode of the ESC;

FIGS. 3A and 3B are surface cross-sectional views of examples of annular edge seals arranged in the lower electrode of the ESC according to the prior art;

FIG. 3C is a surface cross-sectional view of deformation of the annular edge seal of FIG. 3A after use; and

FIG. 4 is a surface cross-sectional view of an example of an annular edge seal according to the present disclosure; and

FIG. 5 is a surface cross-sectional view of an example of the annular edge seal of FIG. 4 arranged on a lower electrode of an ESC according to the present disclosure.

In the drawings, reference numbers may be reused to identify similar and/or identical elements.

### DETAILED DESCRIPTION

Edge seals are used to protect adhesive bonding layers of a lower electrode of an ESC. The edge seals have an annular body with generally rectangular cross-section. In some examples, an outer surface of the annular edge seals is concave and an inner surface is generally planar (e.g. perpendicular to the top and bottom surfaces). The annular edge seal is constrained on 3 surfaces when installed in an annular slot of a lower electrode of the ESC. During use, the annular edge seal is under compression and experiences vertical and radial stresses. If the annular edge seals are not designed appropriately, the annular edge seal may buckle during use. Buckling may lead to failure under certain conditions.

Annular edge seals according to the present disclosure have an improved cross-sectional shape. The annular edge seal according to the present disclosure employs a convex radially inner surface and generally planar radially outer surface. The generally thicker profile of this shape at the vertical center inhibits plasma erosion for longer periods before requiring replacement. The convex curvature of the radially inner surface and the generally planar radially outer surface reduce outward radial stress when installed in an annular slot on the ESC. In other words, the convex geometry of the annular edge seal according to the present disclosure has improved resistance to deformation.

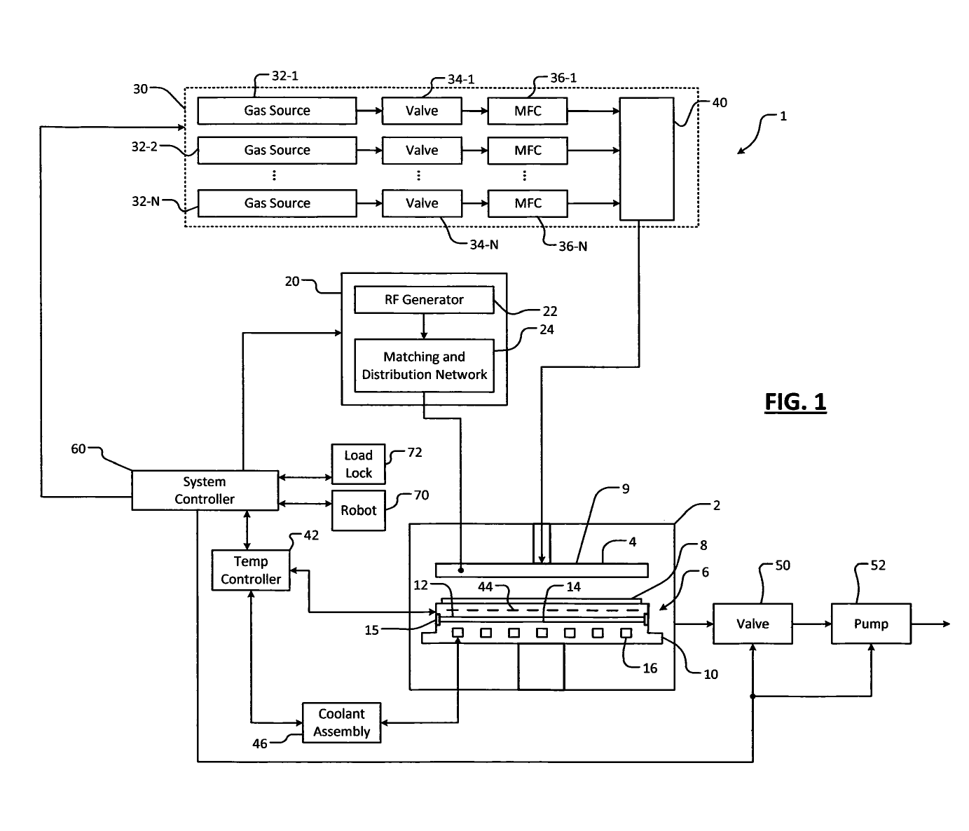

Referring now to FIG. 1, an example of a substrate processing system 1 is shown. While the foregoing example will be described in the context of plasma enhanced atomic layer deposition (PEALD), the present disclosure may be applied to other substrate processing systems that perform etching, chemical vapor deposition (CVD), PECVD, ALE, ALD, PEALE or any other substrate treatment.

The substrate processing system 1 includes a processing chamber 2 that encloses other components of the substrate processing system 1 and contains the RF plasma (if used). The substrate processing system 1 includes an upper electrode 4 and a substrate support 6 such as an electrostatic chuck (ESC), pedestal, etc. During operation, a substrate 8 is arranged on the substrate support 6.

For example only, the upper electrode 4 may include a gas distribution device 9 such as a showerhead that introduces and distributes process gases. The gas distribution device 9 may include a stem portion including one end connected to a top surface of the processing chamber. A base portion is generally cylindrical and extends radially outwardly from an opposite end of the stem portion at a location that is spaced from the top surface of the processing chamber. A substrate-facing surface or faceplate of the base portion of the showerhead includes a plurality of holes through which process gas or purge gas flows. Alternately, the upper electrode 4 may include a conducting plate and the process gases may be introduced in another manner.

The substrate support 6 includes a lower electrode 10. The lower electrode 10 supports a heating plate 12, which may correspond to a ceramic multi-zone heating plate. A thermal resistance layer 14 may be arranged between the heating plate 12 and the lower electrode 10. The lower electrode 10 may include one or more coolant channels 16 for flowing coolant through the lower electrode 10. An annular edge seal 15 may be arranged in an annular slot around one or more layers of the substrate support 6 as will be described further below.

An RF generating system 20 generates and outputs an RF voltage to one of the upper electrode 4 and the lower electrode 10 of the substrate support 6. The other one of the upper electrode 4 and the lower electrode 10 may be DC grounded, AC grounded or floating. For example only, the RF generating system 20 may include an RF generator 22 that generates RF power that is fed by a matching and distribution network 24 to the upper electrode 4 or the lower electrode 10.

A gas delivery system 30 includes one or more gas sources 32-1, 32-2, . . . , and 32-N (collectively gas sources 32), where N is an integer greater than zero. The gas sources 32 are connected by valves 34-1, 34-2, . . . , and 34-N (collectively valves 34) and mass flow controllers 36-1, 36-2, . . . , and 36-N (collectively mass flow controllers 36) to a manifold 40. While a specific gas delivery system 30 is shown, gas may be delivered using any suitable gas delivery systems.

A temperature controller 42 may be connected to a plurality of thermal control elements (TCEs) 44 arranged in the heating plate 12. The temperature controller 42 may be used to control the plurality of TCEs 44 to control a temperature of the substrate support 6 and the substrate 8. The temperature controller 42 may communicate with a coolant assembly 46 to control coolant flow through the coolant channels 16. For example, the coolant assembly 46 may include a coolant pump and reservoir. The temperature controller 42 operates the coolant assembly 46 to selectively flow the coolant through the coolant channels 16 to cool the substrate support 6.

A valve 50 and pump 52 may be used to evacuate reactants from the processing chamber 2. A system controller 60 may be used to control components of the substrate processing system 1. A robot 70 may be used to deliver substrates onto, and remove substrates from, the substrate support 6. For example, the robot 70 may transfer substrates between the substrate support 6 and a load lock 72.

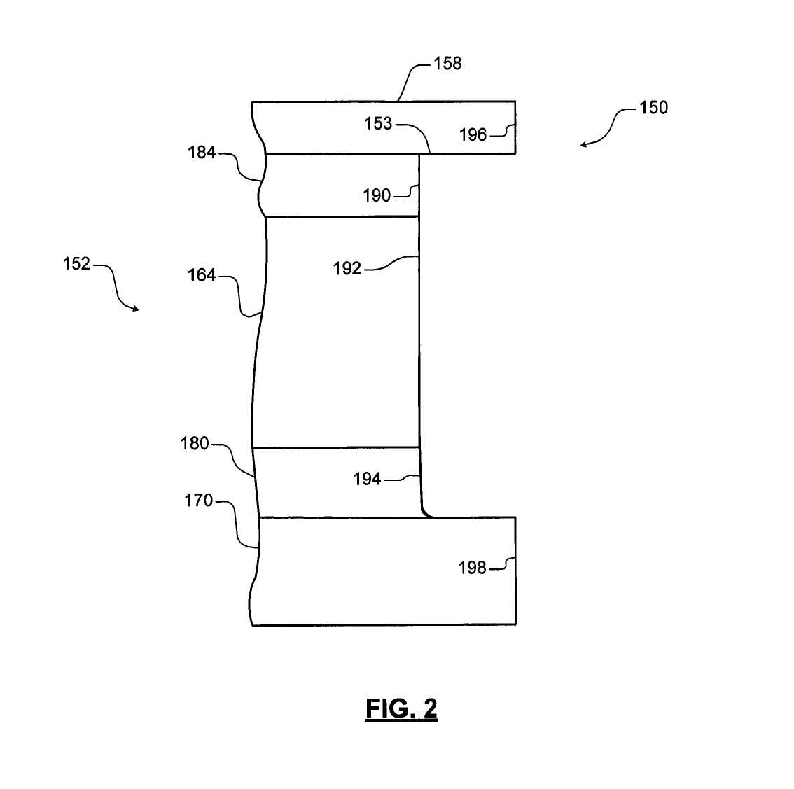

Referring now to FIG. 2, the substrate support 6 may include multiple layers 152 that are bonded together. Radially outer edges of the layers 152 define an annular slot 153 around the substrate support 6. In some examples, the layers 152 of the substrate support 6 include an upper layer 158, an intermediate layer 164 and a lower layer 170. The upper layer 158 may include a ceramic layer, the intermediate layer 164 may include the heater plate 12 and the lower layer 170 may include the lower electrode 10. The heater plate 12 may include a metal or ceramic plate and one or more heaters such as a film heater coupled to a bottom of the plate.

An adhesive bonding layer 180 is arranged between a top surface of the lower layer 170 and a bottom surface of the intermediate layer 164. The adhesive bonding layer 180 bonds the top surface of the lower layer 170 to the bottom surface of the intermediate layer 164. An adhesive bonding layer 184 is arranged between a bottom surface of the upper layer 158 and a top surface of the intermediate layer 164. The adhesive bonding layer 184 bonds the bottom surface of the upper layer 158 to the top surface of the intermediate layer 164.

The upper layer 158 and the lower layer 170 extend radially beyond the intermediate layer 164 and the bonding layers 180, 184 to form the annular slot 153. Radially outer surfaces 190, 192, 194 of the intermediate layer 164 and the adhesive bonding layers 180, 184 are substantially aligned with respect to one another. Radially outer surfaces 196, 198 of the upper layer 158 and the lower layer 170, respectively, may or may not be vertically aligned. Additional or fewer layers may be arranged between the upper and lower layers 158 and 170.

The adhesive bonding layers 180, 184 may include a low modulus material such as an elastomeric silicone or silicone rubber material, although other suitable bonding materials can be used. The thickness of the adhesive bonding layers 180, 184 varies depending on a desired heat transfer coefficient. Thus, the thickness provides a desired heat transfer coefficient based on manufacturing tolerances of the adhesive bonding layers 180, 184.

The heater plate 12 may include a metal or ceramic plate with a film heater coupled to a bottom of the metal or ceramic plate. The film heater can be a foil laminate (not shown) comprising a first insulation layer (e.g., dielectric layer), a heating layer (e.g., one or more strips of electrically resistive material) and a second insulation layer (e.g., dielectric layer). The insulation layers preferably include materials having the ability to maintain physical, electrical and mechanical properties over a wide temperature range including resistance to corrosive gases in a plasma environment.

The adhesive bonding layers 180, 184 are typically not fully resistant to the plasma or reactive etching chemistry of the substrate processing system. To protect the adhesive bonding layers 180, 184, an annular edge seal in the form of an elastomeric band is arranged in the annular slot 153 to form a seal that prevents penetration by the plasma and/or corrosive gases of substrate processing system.

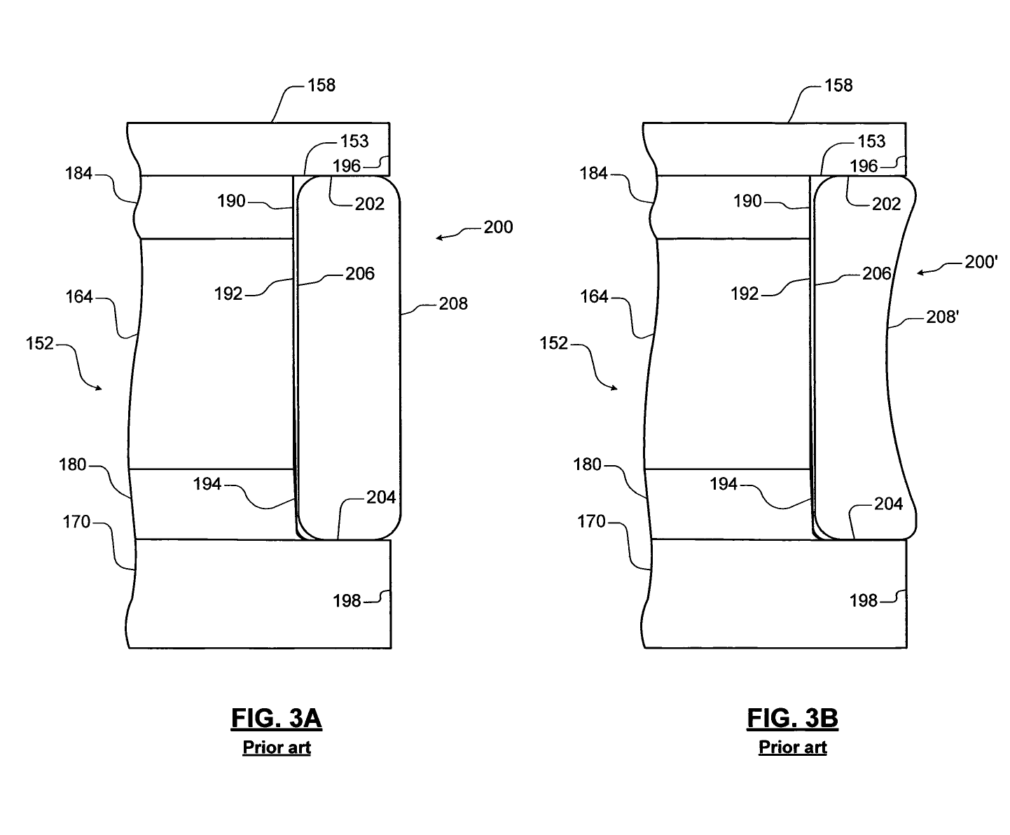

Referring now to FIGS. 3A-3C, examples of annular edge seals according to the prior art are shown. In FIG. 3A, the annular edge seal 200 includes an annular body having a generally rectangular-shaped cross-section with parallel top and bottom surfaces 202 and 204 and parallel surfaces 206 and 208.

In FIG. 3B, the annular edge seal 200′ includes an annular body 201′ with parallel top and bottom surfaces 202 and 204. The inner surface 206 is generally planar (perpendicular to the top and bottom surfaces 202 and 204). An outer surface 208′ is concave.

In FIG. 3C, the annular edge seals 200 and 200′ are shown after use. The annular edge seals 200 and 200′ may experience vertical stresses in additional to other environmental stresses. The vertical stresses may cause the annular edge seals 200 and 200′ to bow radially outwardly away from the annular slot 153. As a result, the annular edge seals 200 and 200′ may not fully protect the adhesive bonding layers 180, 184 and damage to the substrate support 6 or contamination (or both) may occur.

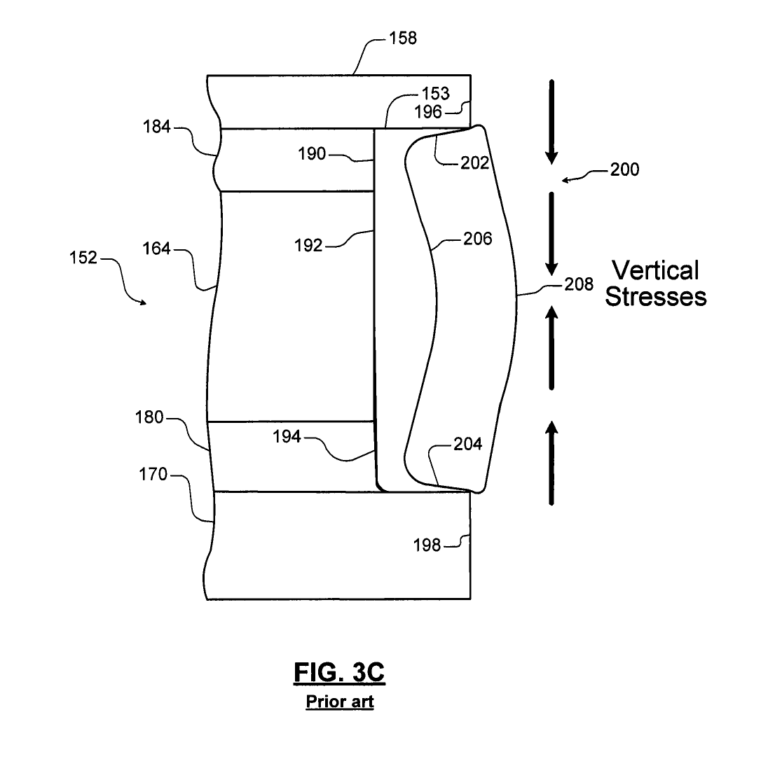

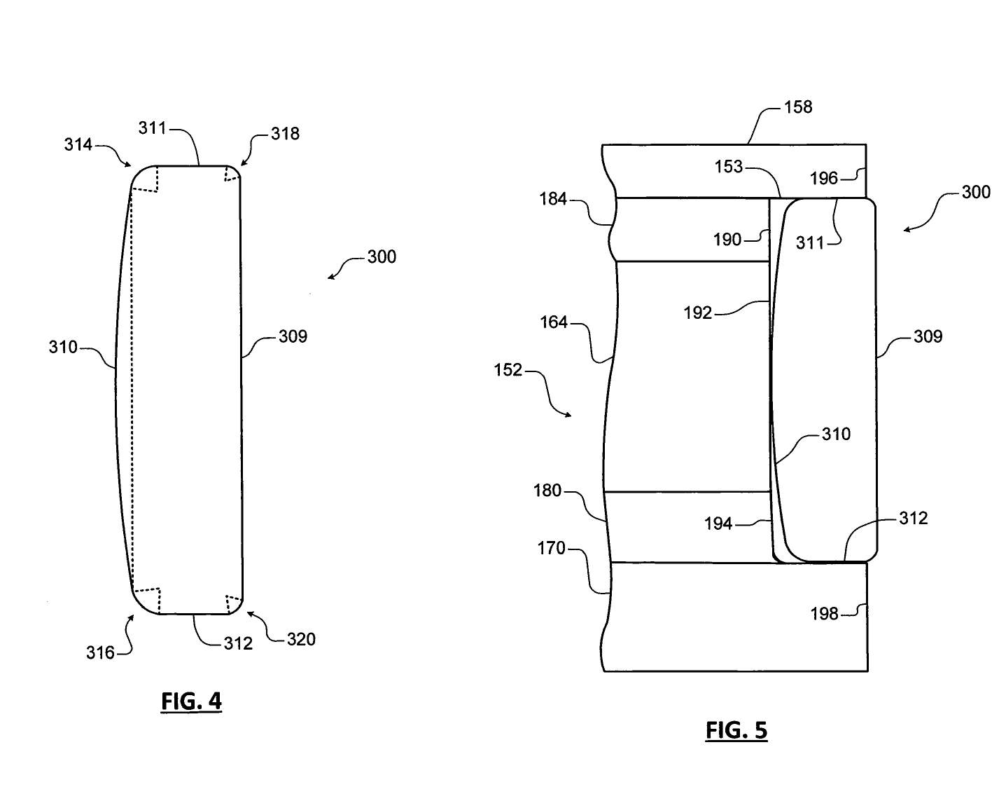

Referring now to FIGS. 4 and 5, an annular edge seal 300 according to the present disclosure is shown. In FIG. 4, the annular edge seal 300 includes an annular body 301 with a radially outer surface 309, a radially inner surface 310, a top surface 311 and a bottom surface 312. The radially outer surface 309 is generally planar and is perpendicular to the top surface 311 and the bottom surface 312. The radially inner surface 310 faces in a radially inwardly direction and is arranged immediately adjacent to the layers 152 (e.g. the upper layer 158, the intermediate layer 164 and the lower layer 170). The radially outer surface 309 faces in a radially outwardly direction. In some examples, the annular edge seal includes corners 314, 316, 318 and 320 that are radiused.

The radially inner surface 310 is convex. In some examples, the thickness of the annular edge seal 300 at a center portion thereof (in a radial direction) is 10%-30% greater than a thickness of the annular edge seal 300 adjacent to the top surface 311 and the bottom surface 312. In other examples, the thickness of the annular edge seal 300 at the center portion thereof is 15%-25% greater than the thickness of the annular edge seal 300 adjacent to the top surface 311 and the bottom surface 312. In still other examples, the thickness of the annular edge seal at the center portion thereof is 22% +/−2% greater than the thickness of the annular edge seal adjacent to the top surface 311 and the bottom surface 312. In some examples, a maximum radial dimension of the edge seal is greater than a radial dimension of the annular slot. In some examples, a maximum axial dimension of the edge seal is approximately (+/−10%) of the axial dimension of the annular slot.

Increased thickness at the center of the edge seal 300 provides additional material to protect the adhesive bonding layers from plasma and/or gas chemistry. The thickness at the center also allows the annular edge seal 300 to resist deformation caused by thermal and compressive stresses. The convex inner surface reduces radial stresses on the annular edge seal, which reduces the tendency of the annular edge seal 300 to buckle (or deform) out of the annular slot.

In FIG. 5, the annular edge seal 300 is shown installed in the annular slot 153 to protect the plurality of layers 152 of the lower electrode 10 from exposure during substrate processing.

As compared to the annular edge seal with concave radially outer surface in FIG. 3B, the annular edge seal with a convex radially inner surface in FIGS. 4 and 5 is estimated to have more than 2 times improved resistance to buckling. In addition, the radial stress is estimated to be higher for the concave annular edge seal as compared to the convex annular edge seal. Significant improvement in the radial stress provides corresponding improvement in resistance to buckling. In addition, there is also a reduction in maximum vertical stress for the convex annular edge seal as compared to the concave annular edge seal.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. An electrostatic chuck comprising:
an upper layer;
an intermediate layer;
a lower layer;
a first adhesive bonding layer arranged between the upper layer and the intermediate layer;
a second adhesive bonding layer arranged between the intermediate layer and the lower layer, wherein radially outer edges of the intermediate layer and the first and second adhesive bonding layers form an annular slot relative to the upper layer and the lower layer; and
an edge seal arranged in the annular slot, wherein the edge seal includes an annular body including a radially inner surface, a radially outer surface, a top surface and a bottom surface, and
wherein the radially inner surface is convex.

2. The edge seal of claim 1, wherein corners between the radially inner surface, the radially outer surface, the top surface and the bottom surface are radiused.

3. The edge seal of claim 1, wherein:
the radially outer surface of the body is generally planar between a first corner between the top surface and the radially outer surface and a second corner between the bottom surface and the radially outer surface;
the top surface of the body is generally planar between a third corner between the top surface and the radially inner surface and a fourth corner between the top surface and the radially outer surface;
the bottom surface of the body is generally planar between the fourth corner between the bottom surface and the radially inner surface and the second corner between the bottom surface and the radially outer surface; and
the radially inner surface of the body is convex between the third corner between the top surface and the radially inner surface and the first corner between the bottom surface and the radially inner surface.

4. The edge seal of claim 1, wherein a radial thickness of the body at a center of the body is 10% to 30% greater than a radial thickness of the body adjacent to the top surface and the bottom surface.

5. The edge seal of claim 1, wherein a radial thickness of the body at a center of the body is 15% to 25% greater than a radial thickness of the body adjacent to the top surface and the bottom surface.

6. The edge seal of claim 1, wherein a radial thickness of the body at a center of the body is 20% to 24% greater than a radial thickness of the body adjacent to the top surface and the bottom surface.

7. The electrostatic chuck of claim 1, wherein the upper layer includes a ceramic layer, the intermediate layer includes a heater plate and the lower layer includes a lower electrode.

8. The electrostatic chuck of claim 7, wherein the first and second adhesive bonding layers include elastomeric silicone.

9. The electrostatic chuck of claim 7, wherein the first and second adhesive bonding layers include silicone rubber.

10. A substrate processing system comprising:
a processing chamber;
a gas delivery system to deliver process gas to the processing chamber;
a plasma generator to generate plasma in the processing chamber; and
the electrostatic chuck of claim 1.

11. An edge seal for an electrostatic chuck of a substrate processing system, the edge seal comprising:
an annular body;
a radially inner surface of the body, wherein the radially inner surface is convex;
a radially outer surface of the body, wherein the radially outer surface of the body is generally planar between a first corner between the top surface and the radially outer surface and a second corner between the bottom surface and the radially outer surface;
a top surface of the body; and
a bottom surface of the body.

12. The edge seal of claim 11 wherein corners between the radially inner surface, the radially outer surface, the top surface and the bottom surface are radiused.

13. The edge seal of claim 11, wherein:
the top surface of the body is generally planar between a third corner between the top surface and the radially inner surface and a fourth corner between the top surface and the radially outer surface;
the bottom surface of the body is generally planar between the fourth corner between the bottom surface and the radially inner surface and the second corner between the bottom surface and the radially outer surface; and
the radially inner surface of the body is convex between the third corner between the top surface and the radially inner surface and the fourth corner between the bottom surface and the radially inner surface.

14. The edge seal of claim 11, wherein a radial thickness of the body at a center of the body is 10% to 30% greater than a radial thickness of the body adjacent to the top surface and the bottom surface.

15. The edge seal of claim 11, wherein a radial thickness of the body at a center of the body is 15% to 25% greater than a radial thickness of the body adjacent to the top surface and the bottom surface.

16. The edge seal of claim 11, wherein a radial thickness of the body at a center of the body is 20% to 24% greater than a radial thickness of the body adjacent to the top surface and the bottom surface.

17. An electrostatic chuck comprising:
a ceramic layer;
a heater plate;
a lower electrode;
a first adhesive bonding layer arranged between the ceramic layer and the heater plate;
a second adhesive bonding layer arranged between the heater plate and the lower electrode,
wherein radially outer edges of the heater plate and the first and second adhesive bonding layers form an annular slot relative to the ceramic layer and the lower electrode; and
the edge seal of claim 11, wherein the edge seal is arranged in the annular slot.

18. The electrostatic chuck of claim 16, wherein the first and second adhesive bonding layers include elastomeric silicone.

19. The electrostatic chuck of claim 16, wherein the first and second adhesive bonding layers include silicone rubber.

20. A substrate processing system comprising:
a processing chamber;
a gas delivery system to deliver process gas to the processing chamber;
a plasma generator to generate plasma in the processing chamber; and
the electrostatic chuck of claim 16.
